(19) United States
(12) Patent Application Publication
(10) Pub. No.: US 2025/0336738 A1
(43) Pub. Date: Oct. 30, 2025

(54) ELECTRONIC DEVICES AND METHODS OF MANUFACTURING ELECTRONIC DEVICES

(71) Applicant: Amkor Technology Singapore Holding Pte. Ltd.

(72) Inventors: Ki Yeul Yang, Incheon (KR); Ji Hyun Kim, Incheon (KR); Ji Hun Lee, Gyeonggi-do (KR)

(73) Assignee: Amkor Technology Singapore Holding Pte. Ltd., (omitted)

(21) Appl. No.: 18/782,851

(22) Filed: Jul. 24, 2024

Related U.S. Application Data
(60) Provisional application No. 63/638,782, filed on Apr. 25, 2024.

(51) Int. Cl. H01L 23/18; H01L 23/00; H01L 23/498; H01L 23/528

(52) U.S. Cl. CPC H01L 23/18; H01L 23/49816; H01L 23/5283; H01L 23/562

(57) ABSTRACT

In one example, an electronic device can include an active region, a buried oxide layer over the active region, and a stiffener disposed over first end of the buried oxide layer and a second end of the buried oxide layer opposite the first end. Inner sidewalls of the stiffener can define a cavity over the buried oxide layer. A passivation layer can be disposed on the inner sidewalls of the stiffener, in the cavity, and over the buried oxide layer. A body can be disposed over the passivation layer and in the cavity. Other examples and related methods are also disclosed herein.

### PRIORITY CLAIM

This present application claims the benefit of U.S. Provisional Patent Application No. 63/638,782 filed on Apr. 25, 2024, which is incorporated herein by reference.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIGS. 1 and 1A show a cross-sectional view of an example electronic device.

FIGS. 2A to 21 show an example method for manufacturing an example electronic device using cross-sectional views.

FIG. 3 shows a cross-sectional view of an example electronic device.

FIG. 4 shows a cross-sectional view of an example electronic device.

FIG. 5 shows a cross-sectional view of an example electronic device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of the stated features, but do not preclude the presence or addition of one or more other features.

The terms “first,” “second,” etc. may be used herein to describe various elements, and the elements described using first, second, etc. should not be limited by these terms. The terms “first,” “second,” etc. are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements. As used herein, the term “coupled” can refer to an electrical or mechanical coupling.

### DESCRIPTION

An example electronic device can include an active region, a buried oxide layer over the active region, and a stiffener disposed over first end of the buried oxide layer and a second end of the buried oxide layer opposite the first end. Inner sidewalls of the stiffener can define a cavity over the buried oxide layer. A passivation layer can be disposed on the inner sidewalls of the stiffener, in the cavity, and over the buried oxide layer. A body can be disposed over the passivation layer and in the cavity.

In various examples, a mask can be disposed between a top side of the stiffener and the passivation layer. A top side of the passivation layer disposed over the stiffener can be exposed from the body. The body can be disposed over the stiffener. A top side of the body can be coplanar with a top side of the passivation layer over the stiffener. A lateral side of the passivation layer, a lateral side of the stiffener, a lateral side of the buried oxide layer, and a lateral side of the active region can be coplanar. An interconnect structure can be coupled to a back-end-of-line region of the active region. A front-end-of-line region of the active region can be coupled to the buried oxide layer. The stiffener can be disposed over a perimeter of the buried oxide layer. The stiffener can comprise a semiconductor material. The body can comprise a mold material and an alumina filler. A portion of a device wafer can be removed to leave the stiffener, the buried oxide layer, and the active region.

An example method of manufacturing an electronic device can include the steps of providing a device wafer including an active region over a buried oxide layer, removing material from a back side of the device wafer opposite the active region to leave a stiffener coupled to the buried oxide layer, and providing a passivation layer coupled to the inner sidewalls of the stiffener, disposed in a cavity, and disposed over the buried oxide layer. Inner sidewalls of the stiffener can define the cavity over the buried oxide layer. A body can be provided in the cavity.

In various examples, a mask can be provided over the stiffener. The passivation layer can be provided over the mask. A top side of the passivation layer disposed over the stiffener can be exposed from the body. The body can be disposed over the stiffener. A top side of the body can be coplanar with a top side of the passivation layer disposed over the stiffener. The example method can include singulating the electronic device through the passivation layer, the stiffener, the buried oxide layer, and the active region. The body can comprise a mold material and an alumina filler. The stiffener can be disposed over a perimeter of the buried oxide layer.

Other examples are included in the present disclosure. Such examples may be found in the figures, in the claims, or in the description of the present disclosure.

Various examples of the present disclosure include silicon on insulator (SOI) devices reinforced by stiffening structures. The SOI devices can be backed with mold material and with semiconductor material to provide good electrical performance and good mechanical properties. Semiconductor material can be used as a stiffener around a mold core or mold backing material. Some examples can be compatible with silicon saw techniques and tooling while still providing conductivity benefits of a mold with a metallic filler. Silicon saw techniques can result in reduced wear imparted on saw blades relative to saw techniques used to cut through mold with metallic filler.

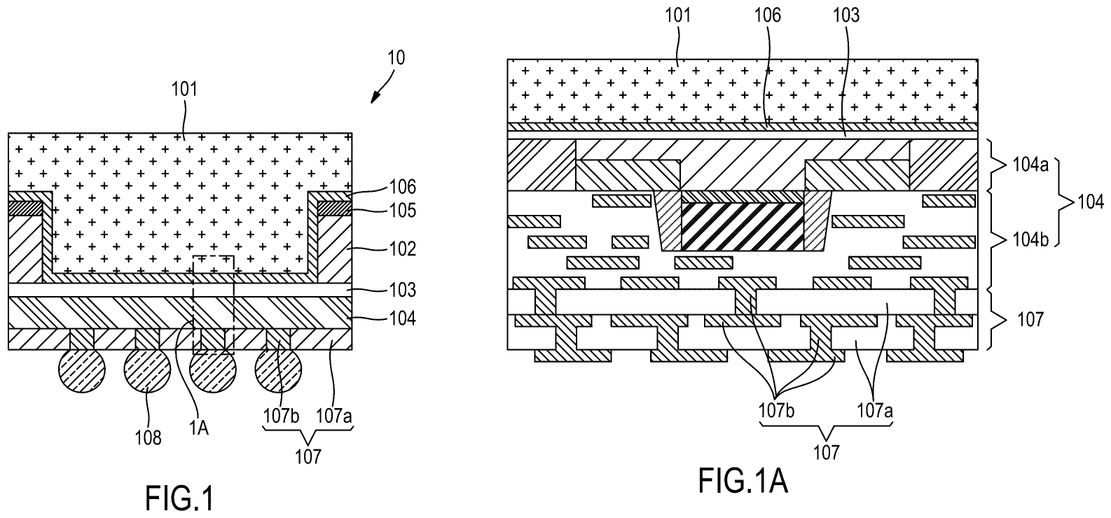

FIG. 1 shows a cross-sectional view of example electronic device 10, in accordance with various examples. In the example shown in FIG. 1, electronic device 10 comprises body 101, stiffener 102, buried oxide layer 103, active region 104, mask 105, passivation layer 106, interconnect structure 107, and external interconnects 108.

FIG. 1A shows an enlarged cross-sectional view of electronic device 10 in region 1A of FIG. 1, in accordance with various examples. In the example shown in FIGS. 1 and 1A, active region 104 can comprise front-end-of-line (FEOL) region 104a and back-end-of-line (BEOL) region 104b. Interconnect structure 107 can comprise dielectric structure 107a and conductive structure 107b.

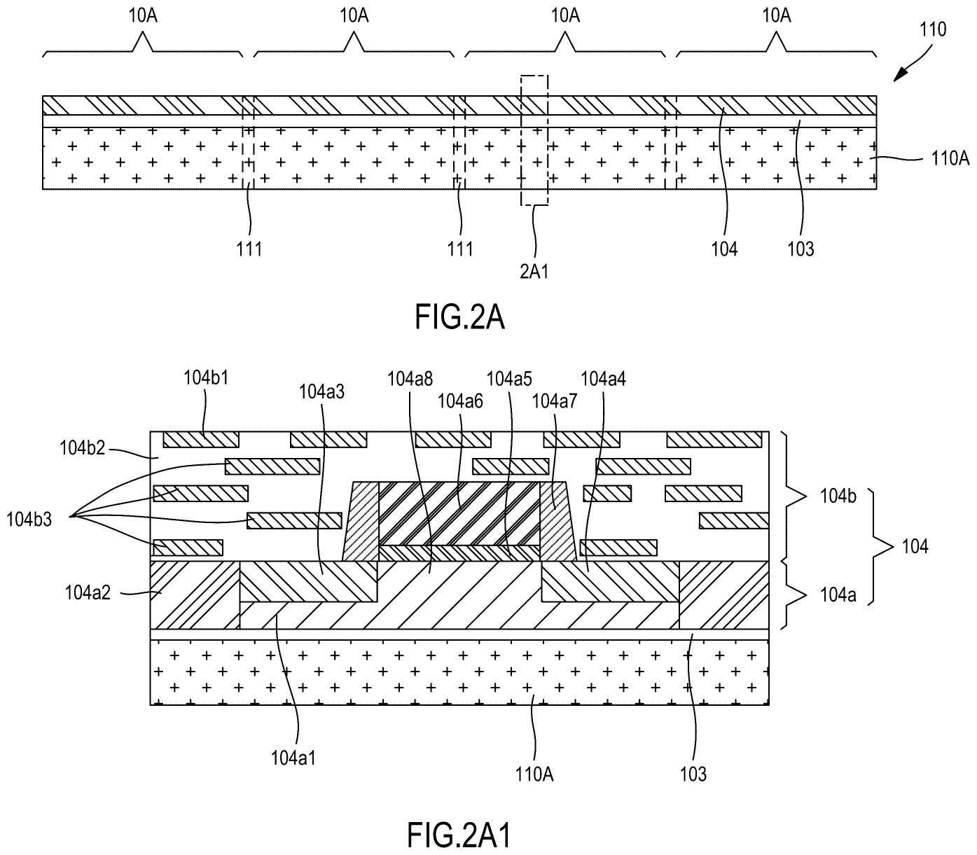

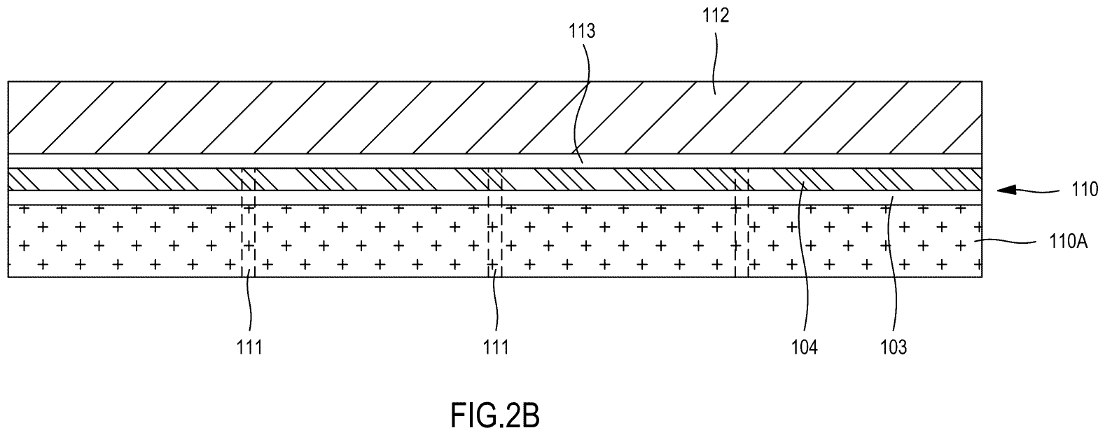

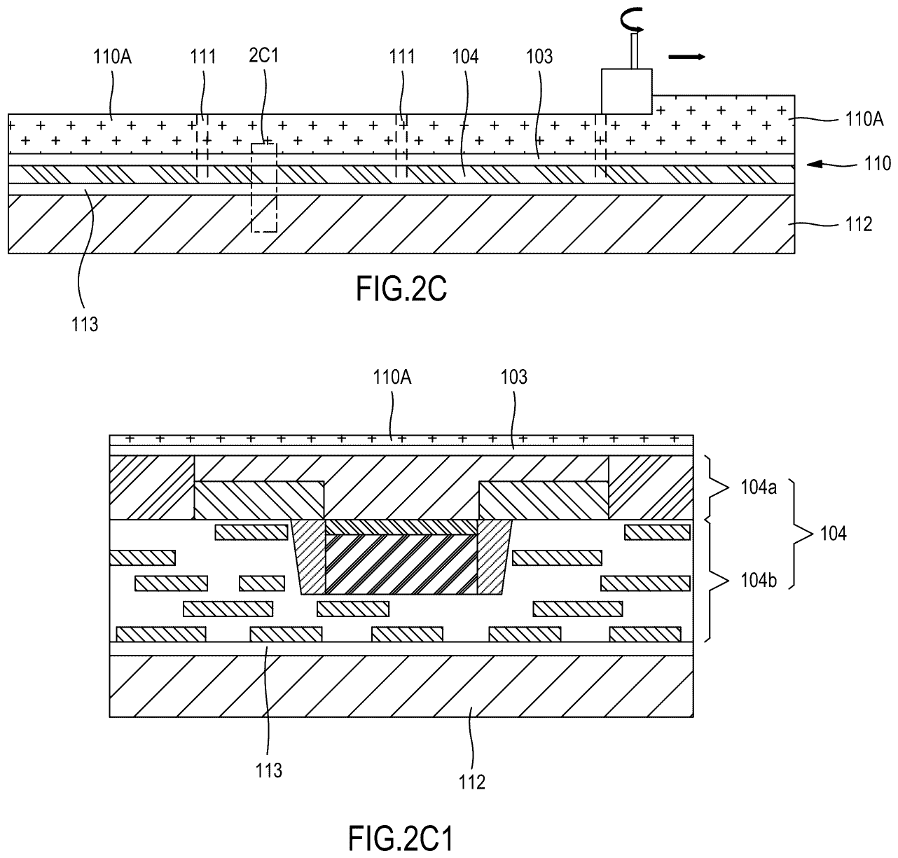

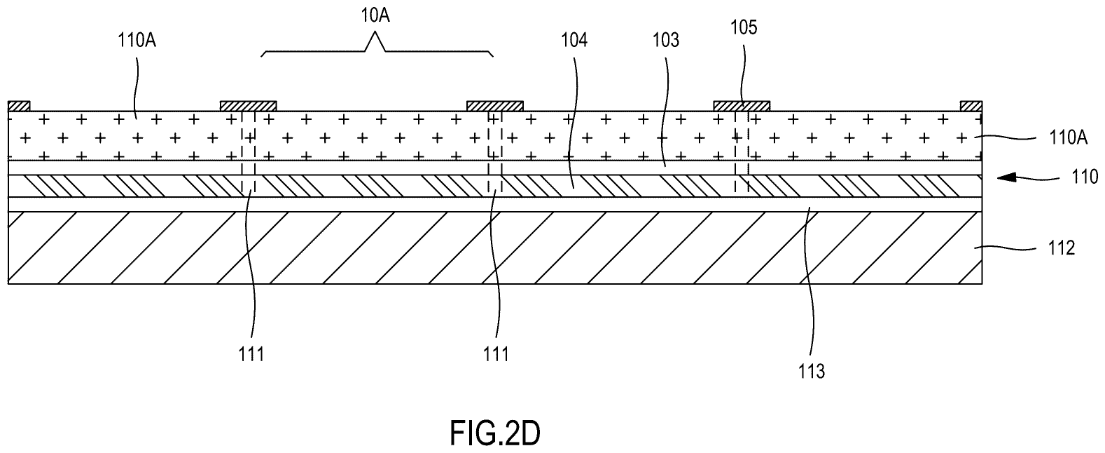

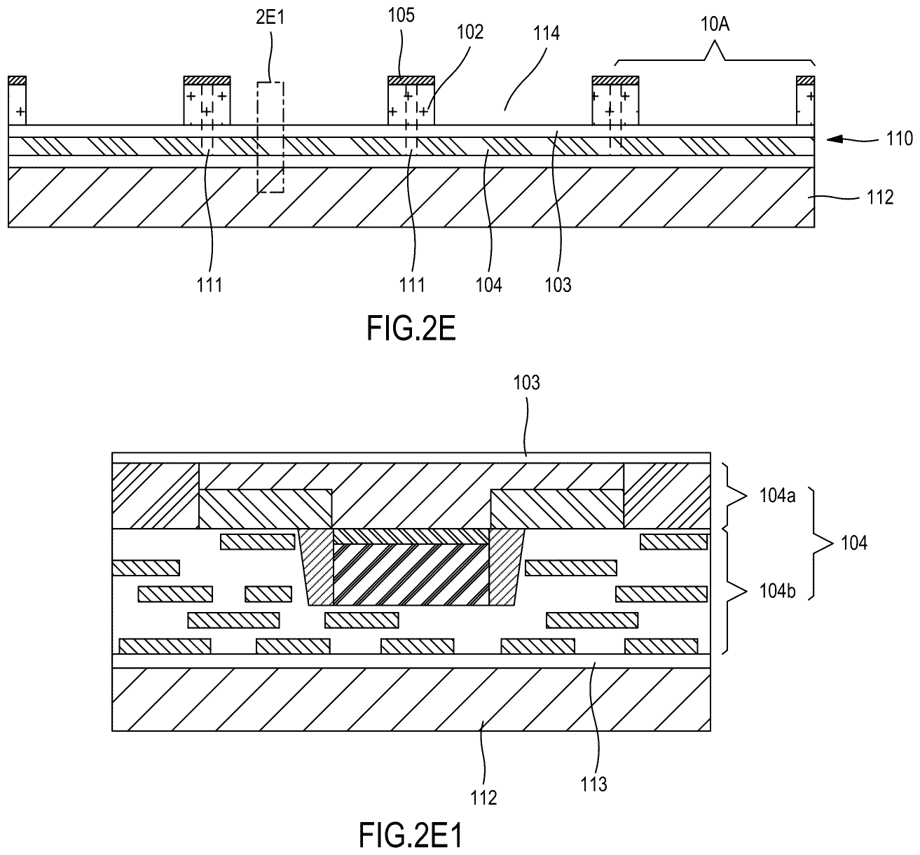

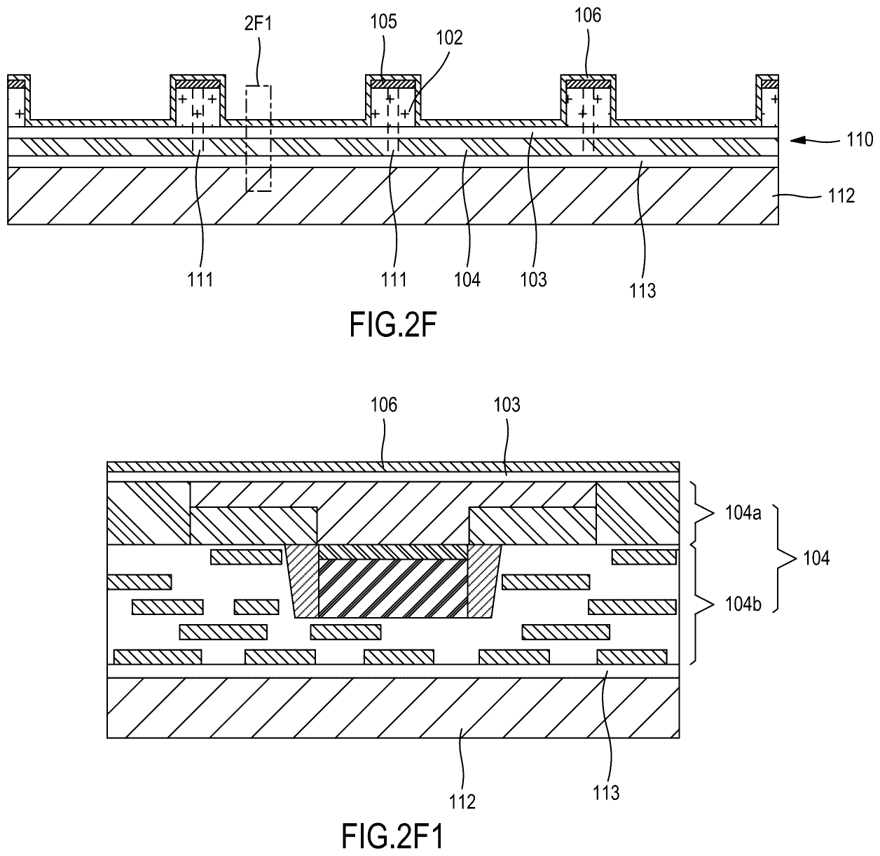

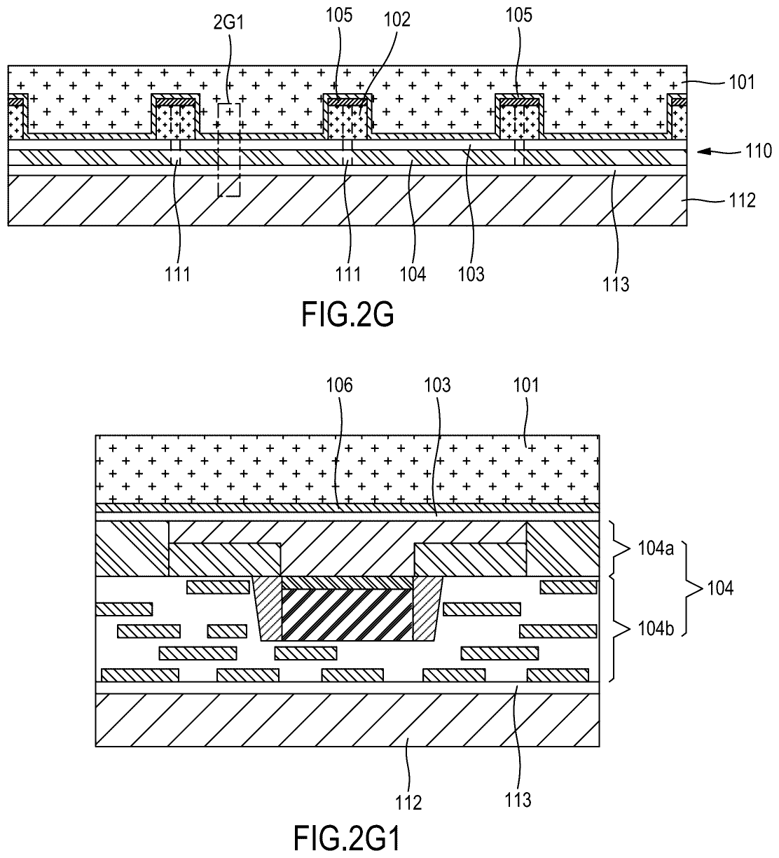

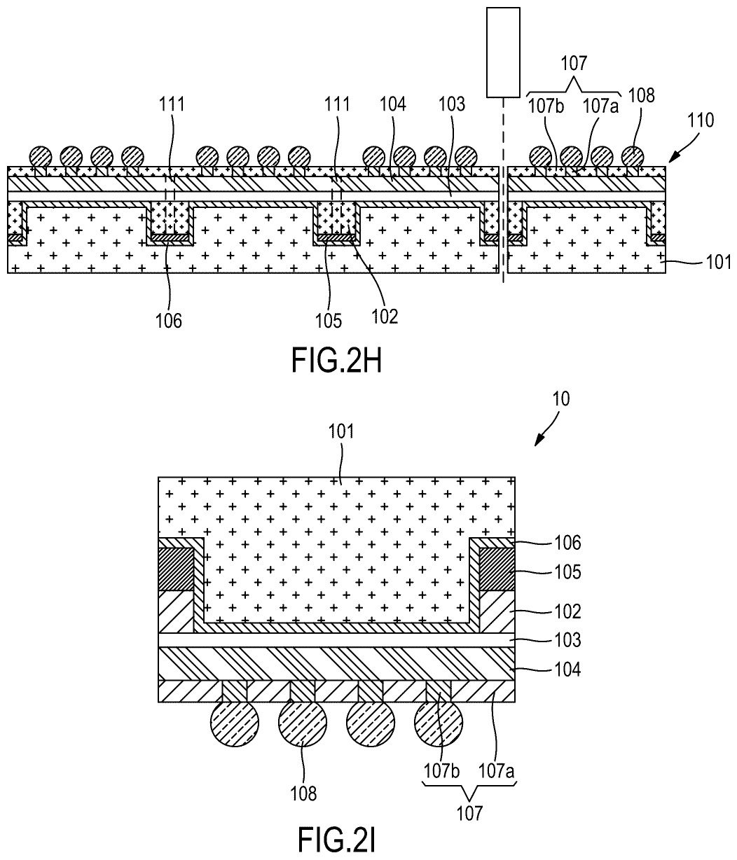

FIGS. 2A-21 illustrate an example method for manufacturing an example electronic device 10 using cross-sectional views, in accordance with various examples. FIG. 2A shows electronic device 10 at an early stage of manufacture. FIG. 2Al shows an enlarged view of electronic device 10 in region 2A1 of FIG. 2A. In the example shown in FIGS. 2A and 2A1, device wafer 110 having base material 110A, buried oxide layer 103, and active region 104 is provided.

In accordance with various examples, buried oxide layer 103 can be located over the top side of base material 110A, and active region 104 can be located over the top side of buried oxide layer 103. Buried oxide layer 103 can be interposed between base material 110A and active region 104. In some examples, buried oxide layer 103 can comprise or be referred to as a silicon oxide layer (SiO2). Buried oxide layer 103 can electrically isolate or insulate active region 104 from base material 110A. In some examples, the thickness of buried oxide layer 103 can range from approximately 0.01 micrometers (μm) to approximately 2 μm. As used herein with numeric values, the term approximately can mean +/−5%, +/−10%, +/−15%, +/−20%, or +/−25%. In some examples, buried oxide layer 103 can be provided by coupling a first wafer comprising base material 110A and an oxide layer located thereon to a second wafer. After bonding and annealing, buried oxide layer 103 can be sandwiched between the first wafer and second wafer. Active region 104 can be grown after bonding the first wafer to the second wafer. In some examples, buried oxide layer 103 can be provided by implanting oxygen into base material 110A and then annealing. Active region 104 can be grown on the top side of buried oxide layer 103. In some examples, device wafer 110, including buried oxide layer 103, can comprise or be referred to as a silicon on insulator (SOI) wafer.

In various examples, base material 110A can comprise a semiconductor material or wafer material, such as, for example, silicon (Si), germanium (Ge), gallium arsenide (GaAs), silicon carbide (SiC), or gallium nitride (GaN). In some examples, the width or diameter of device wafer 110 can range from approximately 50 millimeters (mm) to approximately 300 mm. In some examples, the diameter or width of device wafer 110 can be greater than 300 mm. It will be appreciated that the larger the diameter, the more active regions 104 or electronic devices 10 can included in device wafer 110. The thickness of device wafer 110 can range from approximately 400 μm to approximately 1600 μm, and in some examples, the wafer thickness can be reduced to be in the range from approximately 70 μm to approximately 100 μm through a wafer backgrinding process.

In some examples, active region 104 can comprise or be referred to as an active side. Active region 104 can comprise FEOL region 104a located over the top side of buried oxide layer 103 and BEOL region 104b located on the top side of FEOL region 104a. FEOL region 104a can comprise various layers and patterns for creating devices such as transistors, capacitors, or resistors. For example, FEOL region 104a can be provided on device wafer 110 through oxidation, diffusion, ion implantation, a lithography process, etc. BEOL region 104b can be composed of a conductive structure and a dielectric structure for connecting elements provided in FEOL region 104a. The dielectric and conductive structures of BEOL region 104b can be formed using, for example, chemical vapor deposition (CVD) and physical vapor deposition (PVD), and each layer can be patterned through lithography and etching. In some examples, the thickness of active region 104 can range from approximately 0.01 μm to approximately 50 μm.

In some examples, FEOL region 104a can comprise semiconductor body 104al, isolation region 104a2 (e.g., shallow trench isolation (STI)) provided around semiconductor body 104a1), source region 104a3 and drain region 104a4 provided on semiconductor body 104al, gate insulating film 104a5 provided between source region 104a3 and drain region 104a4, gate region 104a6 provided on gate insulating film 104a5, and sidewall spacer 104a7 covering lateral sides of gate insulating film 104a5 and gate region 104a6. The region between source region 104a3 and drain region 104a4 in semiconductor body 104al can define or be referred to as channel region 104a8. In some examples, isolation region 104a2, source region 104a3, drain region 104a4, gate insulating film 104a5, gate region 104a6, sidewall spacer 104a7, and channel region 104a8 can comprise or be referred to as a transistor (e.g., a field-effect transistor (FET), a metal-oxide semiconductor field-effect transistor (MOSFET), an insulated gate bipolar transistor (IGBT), a complementary metal-oxide-semiconductor (CMOS), etc.). In some examples, FEOL region 104a can include millions or billions of transistors, capacitors, or resistors.

In accordance with various examples, BEOL region 104b is configured to interconnect the components (e.g., transistors, capacitors, or resistors) of FEOL region 104a. BEOL region 104b comprises dielectric structure 104b2 and conductive structure 104b3. Dielectric structure 104b2 can be provided over FEOL region 104a using PVD, CVD, metal organic chemical vapor deposition (MOCVD), atomic layer deposition (ALD), low pressure chemical vapor deposition (LPCVD), plasma enhanced chemical vapor deposition (PECVD), printing, lamination, spin coating, spray coating, sintering, thermal oxidation, or any other suitable deposition process. Dielectric structure 104b2 can comprise one or more layers of inorganic dielectric material, such as, SiO2, Si3N4, SION, SiCN, Ta2O5, or Al2O3. Conductive structure 104b3 can be provided within and/or interleaved with layers of dielectric structure 104b2. Conductive structure 104b3 can be formed using PVD, CVD, MOCVD, ALD, LPCVD, PECVD, electrolytic plating, electroless plating process, or any other suitable metal deposition process. In some examples, conductive structure 104b3 can comprise one or more layers of Cu, Al, Au, Ag, Ni, Ti, TiW, Pd, Pt, or other suitable electrically conductive material. In some examples, conductive structure 104b3 can comprise horizontal traces and vertical vias. Conductive structure 104b3 can be electrically connected to source region 104a3, drain region 104a4, or gate region 104a6.

In various examples, bond pads 104b1 can be provided at the outer side of dielectric structure 104b2 (e.g., at the side opposite FEOL region 104a). Bond pads 104b1 can be coupled to conductive structure 104b3. In some examples, bond pads 104b1 and can comprise a source pad electrically connected to source region 104a3, a drain pad electrically connected to drain region 104a4, and a gate pad electrically connected to gate region 104a6. Bond pads 104b1 can be provided using PVD, CVD, MOCVD, ALD, LPCVD, PECVD, electrolytic plating, electroless plating process, or any other suitable metal deposition process. Bond pads 104b1 can comprise Al, Cu, Au, Ag, Ni, Ti, TiW, Pd, Pt, or any other suitable electrically conductive material. In some examples, bond pads 104b1 can comprise under bump metallization (UBM) to improve bonding with external interconnects 108 (FIG. 1). In some examples, a solder resist defining openings that expose bond pads 104b1 can be provided on the outer side of dielectric structure 104b2.

In some examples, device wafer 110 can have multiple individual devices 10A arranged in rows and columns on a horizontal plane. Saw streets 111 can be located between adjacent individual devices 10A. Saw streets 111 can be a sacrificial portion of device wafer 110 that is cut through during singulation. In some examples, the width of saw street 111 can range from approximately 5 μm to approximately 1000 μm.

FIG. 2B shows electronic device 10 at a later stage of manufacture. In the example shown in FIG. 2B, carrier 112 can be coupled device wafer 110. Carrier 112 can be a substantially planar plate. In some examples, carrier 112 can comprise or be referred to as a plate, board, wafer, panel, or strip. For example, carrier 112 can be provided as a wafer. In some examples, the thickness of carrier 112 can range from approximately 300 μm to approximately 2000 μm, and the width of carrier 112 can range from approximately 100 mm to approximately 300 mm. In some examples, the width of carrier 112 can be greater than 300 mm. In some examples, the width of carrier 112 can be equal to, or slightly greater than, the width of device wafer 110. Carrier 112 can support device wafer 110 or protect active region 104 during processing to provide body 101, stiffener 102, mask 105, and passivation layer 106, as described below.

In various examples, carrier 112 can comprise a temporary bond layer 113. Temporary bond layer 113 can be provided on the surface of carrier 112. Carrier 112 can be coupled to device wafer 110 with temporary bond layer 113 oriented towards or contacting active region 104. Temporary bond layer 113 can be provided on the surface of carrier 112 by a coating method such as spin coating, doctor blade coating, casting, painting, spray coating, slot die coating, curtain coating, slide coating, or knife-over-edge coating, a printing method such as screen printing, pad printing, gravure printing, flexography printing, offset printing, inkjet printing, an intermediate technology between coating and printing, or can be provided by attachment of a bonding film or bonding tape. In some examples, temporary bond layer 113 can comprise or be referred to as a temporary bonding film, temporary bonding tape, or temporary adhesive coating. For example, temporary bonding layer 113 can be a heat release tape (or film) or an optical release tape (or film), and the adhesive strength of temporary bonding layer 113 can be weakened or removed by heat or light, respectively. Temporary bond layer 113 can allow carrier 112 to be separated from active region 104 before interconnect structure 107, described below, is provided.

FIG. 2C shows electronic device 10 at a later stage of manufacture. FIG. 2C1 shows an enlarged view of electronic device 10 in region 2C1 of FIG. 2C. In the example shown in FIGS. 2C and 2C1, carrier 112, having device wafer 110 coupled thereto, can be flipped (i.e., rotated) 180° and a portion of the back side of device wafer 110 can be removed.

In accordance with various examples, a portion of base material 110A of device wafer 110 can be removed by backgrinding. For example, backgrinding can be performed by grinding the back side of device wafer 110 (i.e., the side opposite active region 104) to a reference thickness through a large-particle grinding wheel, and then finely adjusting the thickness through a micro-particle grinding wheel. In some examples, after backgrinding the thickness of device wafer 110 can range from approximately 700 μm to approximately 1600 μm.

FIG. 2D shows electronic device 10 at a later stage of manufacture. In the example shown in FIG. 2D, mask 105 can be provided on device wafer 110. Mask 105 can be provided to cover the top side of saw street 111 in device wafer 110 and the top side of an edge area of individual devices 10A that is adjacent to saw streets 111. Mask 105 can be made of an electrically insulating material such as polyimide (PI), polymer, or polybenzoxazole (PBO). Mask 105 can be provided on the top side of device wafer 110 by spin coating, spray coating, dip coating, or rod coating. Before mask 105 is provided, a photoresist pattern can be provided to cover the central area of individual devices 10A in device wafer 110, and mask 105 can then be provided on the exposed portions of the top side of device wafer 110. After mask 105 is provided, the photo resist pattern can be removed. In some examples, the width of mask 105 can be greater than the width of saw street 111. For example, the width of mask 105 can range from approximately 10 μm to approximately 1005 μm, from approximately 9 μm to approximately 1,100 μm, from approximately 8 μm to approximately 1,200 μm, from approximately 7 μm to approximately 1,300 μm or from approximately 6 μm to approximately 1,400 μm, or any suitable width to cover saw street 111. In some examples, the thickness of mask 105 can range from approximately 5 μm to approximately 50 μm.

FIG. 2E shows electronic device 10 at a later stage of manufacture. FIG. 2E1 shows an enlarged view the electronic device 10 in region 2E1 of FIG. 2E. In the example shown in FIGS. 2E and 2E1, portions of base material 110A of device wafer 110 located outside the footprint of mask 105 are removed. The portions of base material 110A that remain become stiffener 102. Semiconductor material can be removed from a central region of device wafer 110 to leave stiffener 102 over buried oxide layer 103. Stiffener 102 can be interposed between mask 105 and buried oxide layer 103. Stiffener 102 can comprise a portion of base material 110A of device wafer 110. For example, base material 110A of device wafer 110 can be patterned through etching, so portions of base material 110A below mask 105 remain. The width of stiffener 102 can be similar to the width of mask 105. In some examples, stiffener 102 can comprise or be referred to as a wafer, semiconductor material, or silicon.

In various examples, cavity 114 is defined between inner sidewalls of adjacent stiffeners 102 and in the central area of individual device 10A. The lateral boundaries of cavity 114 can be defined by mask 105 and stiffener 102, and the lower boundary of cavity 114 by an upper side of buried oxide layer 103. In some examples, mask 105 and stiffener 102 can have a square or rectangular geometry encircling or surrounding cavity 114 when viewed from above. Stiffener 102 can be disposed over the perimeter of buried oxide layer 103. Buried oxide layer 103 located in the center area of individual device 10A can be exposed through the cavity.

FIG. 2F shows electronic device 10 at a later stage of manufacture. FIG. 2F1 shows an enlarged view of electronic device 10 in region 2F1 of FIG. 2F. In the example shown in FIGS. 2F and 2F1, passivation layer 106 is be provided over device wafer 110.

In accordance with various embodiments, passivation layer 106 can cover stiffeners 102, buried oxide layer 103, and mask 105. Passivation layer 106 can be coupled to the sidewalls of stiffeners 102, the top side of buried oxide layer 103, and the top side and sidewalls of mask 105. Passivation layer 106 can comprise or be referred to as a silicon oxide film (SiO2) or a silicon nitride film (SiN). In some examples, passivation layer 106 can be formed by PVD, CVD, MOCVD, ALD, LPCVD, PECVD, coating, (e.g., spin coating, spray coating, dip coating, rod coating, etc.) printing, lamination, sintering, thermal oxidation, or any other suitable deposition process. In some examples, the thickness of passivation layer 106 can range from approximately 1 μm to approximately 20 μm.

FIG. 2G shows electronic device 10 at a later stage of manufacture. FIG. 2G1 shows an enlarged view of the electronic device 10 in region 2G1 of FIG. 2G. In the example shown in FIGS. 2G and 2G1, body 101 can be provided over passivation layer 106.

In accordance with various examples, body 101 can contact, can cover, or can be coupled to the top side of passivation layer 106. Passivation layer 106 can be interposed between mask 105 and body 101, between stiffener 102 and body 101, and between buried oxide layer 103 and body 101. Passivation layer 106 can provide electrical insulation between body 101 and device wafer 110 (e.g., between body 101 and active region 104).

In accordance with various examples, body 101 can comprise an epoxy mold compound, resin, a sealant, a B-stage pressed film, a gel, an organic body, an organic polymer with an inorganic filler, a hardener, a catalyst, a coupling agent, a colorant, or a flame retardant. Body 101 can be formed by a compression molding process, a transfer molding process, a liquid phase body molding process, a vacuum lamination process, a paste printing process, or a film assisted molding process. Body 101 can have greater strength or greater density than stiffener 102. Body 101 can comprise a high thermal conductivity mold. For example, body 101 can comprise a high-density alumina (e.g., Al2O3) filler to increase the rigidity of electronic device 10. In some examples, body 101 can comprise an epoxy, phenol resin, carbon black, silica filler, or metallic filler.

In various examples, a thickness of body 101 over the top side of stiffener 102 can be less than a thickness of body 101 over a central area outside the footprint of stiffener 102. For example, the thickness of body 101 can range from approximately 700 μm to approximately 1000 μm in a central area outside the footprint of stiffener 102, and the thickness of body 101 over stiffener 102 can range from approximately 0 μm to approximately 300 μm.

After body 101 is provided, carrier 112 can be removed from active region 104. Temporary bond layer 113 of carrier 112 can be removed along with carrier 112 to expose BEOL region 104b of active region 104.

FIG. 2H shows electronic device 10 at a later stage of manufacture. In the example shown in FIG. 2H, device wafer 110 is flipped (i.e., rotated) 180°, such that body 101 is located on the bottom side of device wafer 110, and interconnect structure 107 and external interconnects 108 can be provided over active region 104 of device wafer 110. Interconnect structure 107 can comprise dielectric structure 107a and conductive structure 107b. After dielectric structure 107a is provided to cover the top side of BEOL region 104b of active region 104, an opening can be made in dielectric structure 107a to expose the conductive structure of BEOL region 104b.

For example, after forming a mask pattern on the top side of dielectric structure 107a, the opening can be formed by removing the exposed portions of dielectric structure 107a through etching. The opening can comprise or be referred to as an aperture or hole. In some examples, dielectric structure 107a can comprise or be referred to as a dielectric layer, coreless layer, or filler-free layer. For example, dielectric structure 107a can comprise an electrically insulating material such as polyimide (PI), benzocyclobutene (BCB), polybenzoxazole (PBO), resin, Ajinomoto buildup film (ABF), or solder resist. In some examples, dielectric structure 107a can be formed by spin coating, spray coating, dip coating, or rod coating. In some example, the thickness of dielectric structure 107a can range from approximately 5 μm to approximately 50 μm.

In various examples, conductive structure 107b can be provided in the openings formed in dielectric structure 107a. Interconnect structure 107 can be provided with one or more layers of dielectric structure 107a and conductive structure 107b to cover the top side of BEOL region 104b. Conductive structure 107b can be in contact with and be electrically connected to conductive structure of BEOL region 104b. Conductive structure 107b can be electrically connected to FEOL region 104a through the conductive structure 104b3 of BEOL region 104b. Conductive structure 107b can comprise or be referred to as a conductor, conductive material, pad, lands, or under-bump-metallization. In some examples, conductive structure 107b can comprise copper, gold, silver, or nickel. In some examples, conductive structure 107b can be provided by plating. For example, after a metal seed layer is provided to cover the bond pads 104b1 of BEOL region 104b and a mask pattern is provided to cover the top side of seed layer, conductive structure 107b can be provided through plating to have a pattern by using the seed layer as a seed. In some examples, the mask pattern can comprise a photoresistor. The mask pattern can be removed after conductive structure 107b is formed. In some example, the thickness of conductive structure 107b can range from approximately 1 μm to approximately 20 μm. Dielectric structure 107a can comprise one or more layers. One or more layers or elements of conductive structure 107b can be interleaved with one or more layers of dielectric structure 107a. In some example, the total thickness of interconnect structure 107 can range from approximately 5 μm to approximately 50 μm.

In some examples, interconnect structure 107 can be a redistribution layer (“RDL”) substrate. RDL substrates can comprise one or more conductive redistribution layers and one or more dielectric layers and (a) can be formed layer by layer over an electronic device to where the RDL substrate is to be coupled, or (b) can be formed layer by layer over a carrier and can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask.

The dielectric layers of an RDL substrate can be patterned with a photo-patterning process and can include a photolithographic mask through where light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layer(s) can comprise silicon nitride (Si3N4), silicon oxide (SiO2), and/or SiON. The inorganic dielectric layers can be formed by growing the inorganic dielectric layers using an oxidation or nitridization process instead using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can comprise or be referred to as a coreless substrate. Other substrates in this disclosure can also comprise an RDL substrate.

In some examples, interconnect structure 107 can be a pre-formed substrate. The pre-formed substrate can be manufactured prior to attachment to an electronic device and can comprise dielectric layers between respective conductive layers. The conductive layers can comprise copper and can be formed using an electroplating process. The dielectric layers can comprise non-photo-definable layers, and can be attached as a pre-formed film rather than as a liquid, and can include a resin with fillers such as strands, weaves, and/or other inorganic particles for rigidity or structural support. In examples in which dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4, and dielectric and conductive layers can be formed on the permanent core structure. In some examples, the pre-formed substrate can be a coreless substrate and omits the permanent core structure, and the dielectric and conductive layers can be formed on a sacrificial carrier and is removed after formation of the dielectric and conductive layers and before attachment to the electronic device. The pre-formed substrate can rereferred to as a printed circuit board (PCB) or a laminate substrate. Such pre-formed substrate can be formed through a semi-additive or modified-semi-additive process. Other substrates in this disclosure can also comprise a pre-formed substrate.

In various examples, external interconnects 108 can be coupled to conductive structure 107b of interconnect structure 107. External interconnects 108 can be electrically connected to the components of FEOL region 104a through conductive structure 107b of interconnect structure 107 and conductive structure 104b3 of BEOL region 104b. In some examples, external interconnects 108 can comprise tin (NS), silver (Ag), lead (Pb), copper (Cu), Sn—Pb, Sn37—Pb, Sn95—Pb, Sn—Pb—Ag, Sn—Cu, Sn—Ag, Sn—Au, Sn—Bi, or Sn—Ag—Cu. For example, external interconnects 108 can be formed by forming a conductive material containing solder on conductive structure 107b using a ball drop method and then performing a reflow process. External interconnects 108 can comprise or be referred to as conductive balls such as solder balls, conductive pillars such as copper pillars, or conductive posts each having a solder cap formed on the copper pillars. In some examples, external interconnects 108 are bond pads without bumps, such as input/output pads, and can be connected to the conductive structure of BEOL region 104b. In some examples, the total thickness of external interconnects 108 can range from approximately 1 μm to approximately 1000 μm. In some examples, external interconnects 108 can be referred to as external input/output terminals of electronic device 10.

In some examples, after external interconnects 108 are provided, a singulation process can be performed to separate device wafer 110 into individual electronic devices 10. The singulation process can include sawing through saw streets 111. In some examples, the singulation process can utilize a diamond blade or laser beam. In the singulation process, body 101, passivation layer 106, mask 105, stiffener 102, buried oxide layer 103, active region 104, and interconnect structure 107 can be sawed by a sawing tool and separated into individual electronic devices 10. Body 101 can be harder to cut through than the materials in saw street 111. Since the thickness of body 101 is reduced in saw streets 111 relative to other areas, due to stiffener 102 and mask 105, saw street 111 can better facilitate sawing and tends to prevent breakage.

FIG. 2I shows electronic device 10 at a later stage of manufacture (e.g., after singulation). In the example shown in FIG. 2I, electronic device 10 can comprise body 101, stiffener 102, buried oxide layer 103, active region 104, mask 105, passivation layer 106, interconnect structure 107, and external interconnects 108. In electronic device 10, as the result of sawing, body 101, passivation layer 106, mask 105, stiffener 102, buried oxide layer 103, active region 104, and the sidewalls of interconnect structure 107 can be exposed or coplanar at the side wall of electronic device 10. A thickness of body 101 near the perimeter of electronic device 10 can be less than a thickness of body 101 in the central area of electronic device 10.

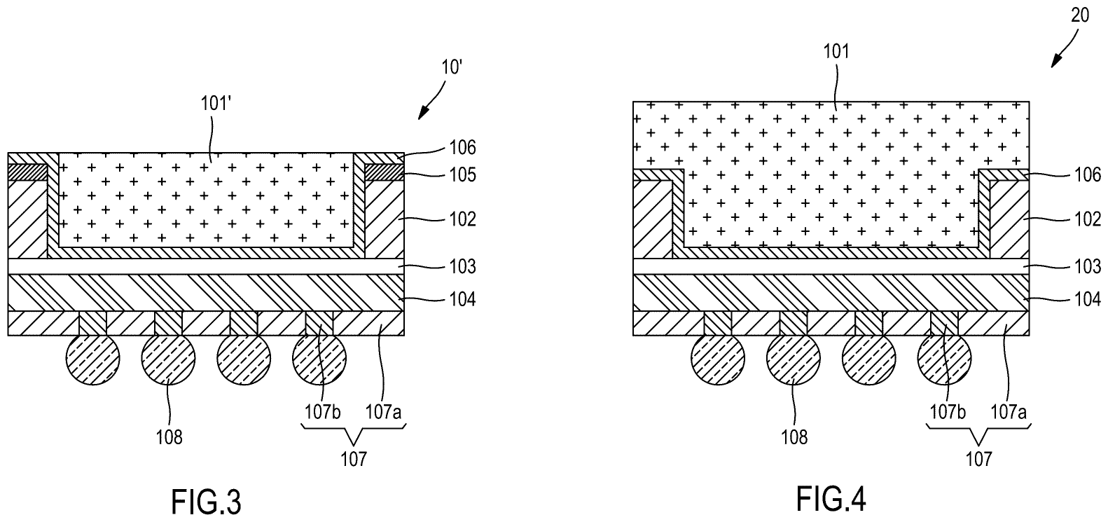

FIG. 3 shows a cross-sectional view of example electronic device 10′. In the example shown in FIG. 3, electronic device 10′ can comprise body 101′, stiffener 102, buried oxide layer 103, active region 104, mask 105, passivation layer 106, interconnect structure 107, and external interconnects 108. Interconnect structure 107 can comprise dielectric structure 107a and conductive structure 107b.

Electronic device 10′ can be similar to electronic device 10. For example, electronic device 10′ can be similar to electronic device 10 in terms of stiffener 102, buried oxide layer 103, active region 104, mask 105, passivation layer 106, interconnect structure 107, and external interconnects 108.

In various examples, body 101′ can be disposed over passivation layer 106 in a central area. The top side of body 101′ can be coplanar with the top side of passivation layer 106 adjacent the edge of electronic device 10′. For example, body 101′ can be provided to cover passivation layer 106, and the upper portion of body 101′ can then be removed to expose the portion passivation layer 106 disposed over the top side of mask 105. Body 101′ can be removed by grinding, etching, or laser ablation. As another example, body 101′ can be provided to fill the cavity in the central area between stiffeners 102. In some examples, body 101′ can be provided to cover the top side of passivation layer 106, and the upper portion of body 101′ can then be removed by grinding. In some examples body 101′ can be provided to fill the cavity without extending out of the central cavity and over the top surface of passivation layer 106. The thickness of body 101′ can range from approximately 10 μm to approximately 500 μm. Body 101′ can comprise elements, features or materials corresponding to those of body 101.

FIG. 4 shows a cross-sectional view of example electronic device 20. In the example shown in FIG. 4, electronic device 20 can comprise body 101, stiffener 102, buried oxide layer 103, active region 104, passivation layer 106, interconnect structure 107, and external interconnects 108. Interconnect structure 107 can comprise dielectric structure 107a and conductive structure 107b.

In accordance with various examples, electronic device 20 can be similar to electronic device 10 (of FIG. 1). For example, electronic device 20 can be similar to electronic device 10 in terms of body 101, stiffener 102, buried oxide layer 103, active region 104, passivation layer 106, interconnect structure 107, and external interconnects 108. Electronic device 20 can lack mask 105 from device 10.

For example, in electronic device 20, stiffener 102 can be patterned through mask 105, and mask 105 can then be removed from stiffener 102. As another example, electronic device 20 can have stiffener 102 patterned with a photoresist, and after stiffener 102 is patterned, the photoresist can be removed. Electronic device 20 can be provided with passivation layer 106 to cover stiffener 102 and buried oxide layer 103. Passivation layer 106 can be coupled to a top side of stiffener 102.

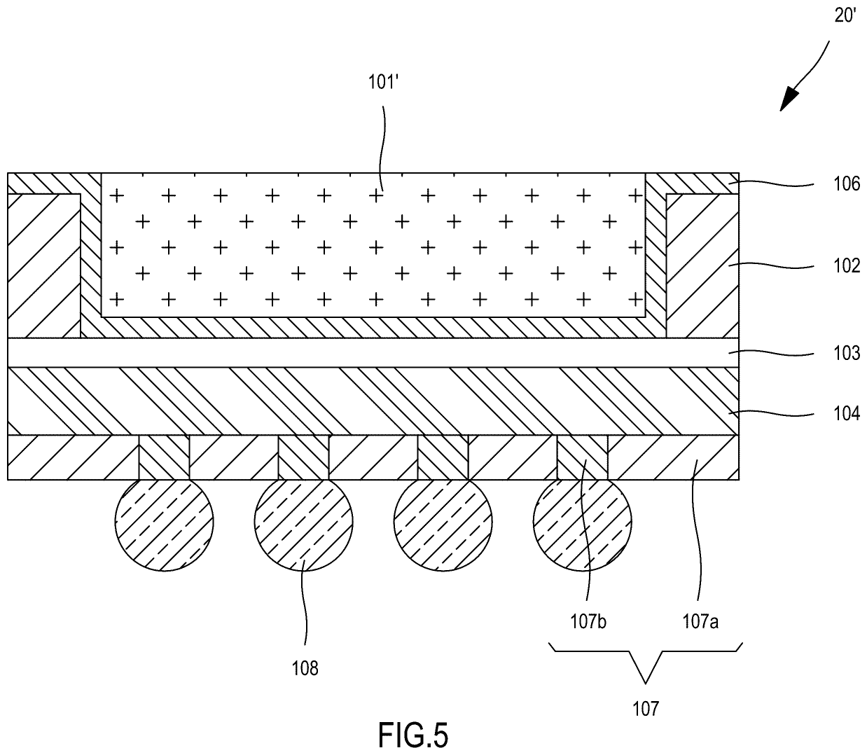

FIG. 5 shows a cross-sectional view of example electronic device 20′. In the example shown in FIG. 5, electronic device 20′ can comprise body 101′, stiffener 102, buried oxide layer 103, active region 104, passivation layer 106, interconnect structure 107, and external interconnects 108. Interconnect structure 107 can comprise dielectric structure 107a and conductive structure 107b.

Electronic device 20′ can be similar to electronic device 20 and electronic device 10. Electronic device 20′ can be similar to electronic device 10 in including stiffener 102, buried oxide layer 103, active region 104, passivation layer 106, interconnect structure 107, and external interconnects 108. Electronic device 20′ can be similar to electronic device 10′ in terms of body 101′ being coplanar with passivation layer 106 near an edge of electronic device 20′. Electronic device 20′ can lack mask 105. Body 101′ can be contained within a central cavity of electronic device 20′ between stiffeners 102. Passivation layer 106 can be disposed on the top side of stiffener 102, and a top side of passivation layer 106 over stiffener 102 can be exposed.

Various examples of electronic devices are reinforced by semiconductor stiffening structures. The SOI devices can be backed with mold material and with semiconductor material to provide good electrical performance and good mechanical properties. Semiconductor material can be used as a stiffener around a mold core or mold backing material. Mold material with alumina filler tends to have good conductive properties.

The present disclosure includes reference to certain examples, however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
an active region;
a buried oxide layer over the active region;
a stiffener disposed over first end of the buried oxide layer and a second end of the buried oxide layer opposite the first end, wherein inner sidewalls of the stiffener define a cavity over the buried oxide layer;
a passivation layer disposed on the inner sidewalls of the stiffener, in the cavity, and over the buried oxide layer; and
a body disposed over the passivation layer and in the cavity.

2. The electronic device of claim 1, further comprising a mask disposed between a top side of the stiffener and the passivation layer.

3. The electronic device of claim 1, wherein a top side of the passivation layer disposed over the stiffener is exposed from the body.

4. The electronic device of claim 1, wherein the body is disposed over the stiffener.

5. The electronic device of claim 1, wherein a top side of the body is coplanar with a top side of the passivation layer over the stiffener.

6. The electronic device of claim 1, wherein a lateral side of the passivation layer, a lateral side of the stiffener, a lateral side of the buried oxide layer, and a lateral side of the active region are coplanar.

7. The electronic device of claim 1, further comprising an interconnect structure coupled to a back-end-of-line region of the active region.

8. The electronic device of claim 1, wherein a front-end-of-line region of the active region is coupled to the buried oxide layer.

9. The electronic device of claim 1, wherein the stiffener is disposed over a perimeter of the buried oxide layer.

10. The electronic device of claim 1, wherein the stiffener comprises a semiconductor material.

11. The electronic device of claim 1, wherein the body comprises a mold material and an alumina filler.

12. The electronic device of claim 1, wherein a portion of a device wafer is removed to leave the stiffener, the buried oxide layer, and the active region.

13. A method of manufacturing an electronic device, comprising:
providing a device wafer including an active region over a buried oxide layer;
removing material from a back side of the device wafer opposite the active region to leave a stiffener coupled to the buried oxide layer, wherein inner sidewalls of the stiffener define a cavity over the buried oxide layer;
providing a passivation layer coupled to the inner sidewalls of the stiffener, disposed in the cavity, and disposed over the buried oxide layer; and
providing a body in the cavity.

14. The method of claim 13, further comprising providing a mask over the stiffener, wherein the passivation layer is provided over the mask.

15. The method of claim 13, wherein a top side of the passivation layer disposed over the stiffener is exposed from the body.

16. The method of claim 13, wherein the body is disposed over the stiffener.

17. The method of claim 13, wherein a top side of the body is coplanar with a top side of the passivation layer disposed over the stiffener.

18. The method of claim 13, further comprising singulating the electronic device through the passivation layer, the stiffener, the buried oxide layer, and the active region.

19. The method of claim 13, wherein the body comprises a mold material and an alumina filler.

20. The method of claim 13, wherein the stiffener is disposed over a perimeter of the buried oxide layer.
